(19) United States
(12) Patent Application Publication
(10) Pub. No.: US 2006/0263934 A1
(43) Pub. Date: Nov. 23, 2006

(54) CHIP-TYPE MICRO-CONNECTOR AND METHOD OF PACKAGING THE SAME

(76) Inventors: Shu-Hua Hu, Tai-Chung City (TW); Kuan-Jui Huang, Kao-Hsiung Hsien (TW); Chin-Chang Pan, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/461,458

(22) Filed: Aug. 1, 2006

Related U.S. Application Data
(62) Division of application No. 10/907,653, filed on Apr. 11, 2005.

(30) Foreign Application Priority Data
Feb. 21, 2005 (TW) 094105076

(51) Int. Cl. H01L 21/00

(52) U.S. Cl. 438/107

(57) ABSTRACT

The chip-type micro-connector includes a package substrate, a micro-connector disposed on the package structure, a plurality of chips, and a cap layer disposed on the micro-connector and the chips. The micro-connector includes a connection substrate, a plurality of connecting wires disposed in the connection substrate, and a plurality of contact pads exposed on a surface of the connection substrate and respectively connected to each connecting wire. The chips are coupled to one another via the contact pads and the connecting wires. The cap layer packages the micro-connector and the chips on the package substrate.

### CROSS REFERENCE TO RELATED APPLICATIONS

This application is a divisional of application Ser. No. 10/907,653 filed Apr. 11, 2005.

### BACKGROUND OF THE INVENTION

1. Field of the Invention

The present invention relates to a chip-type micro-connector and method of packaging the same, and more particularly, to a chip-type micro-connector that utilizes a micro-connector as a communication medium between a plurality of chips, and method of packaging the same.

2. Description of the Prior Art

Recently, multi-functional and miniature electronic products have been rapidly developed. In practice, the multiple functions generally have to be achieved with a plurality of chips. However, if the connections between the chips are fulfilled by a circuit layout of a printed circuit board (PCB), the size of an electronic product gets larger inevitably. Therefore, chips are frequently electrically connected to one another by wiring, and packaged directly as a package structure to fulfill both the multi-function and miniaturization requirements.

Please refer to FIG. 1. FIG. 1 is a schematic diagram of a conventional package structure 10. As shown in FIG. 1, the conventional package structure 10 includes a package substrate 12, and two chips 14 and 16 respectively bonded to the surface of the package substrate 12. The chip 14 includes a plurality of contact pads 14A and 14B, and the chip 16 includes a plurality of contact pads 16A and 16B. The chips 14 and 16 are electrically connected to each other with conducting wire 18. In addition, the chips 14 and 16 are connected to contact pads 24 of the package substrate 12 via the contact pads 14A and 16A with conducting wires 20 and 22.

Generally, the package structure 10 includes a cap layer (not shown) covering the package structure 12 and the chips 14 and 16, and a plurality of solder bumps (not shown) or pins (not shown) with different standards for installing the package structure onto a PCB (not shown).

The chips 14 and 16 communicate with each other with the conducting wires 18. If the distance between the chip 14 and the chip 16 is too far, the conducting wires 18 may become loose, and the resistance of the wires 18 may become too large. In addition, the size of the package structure 10 increases accordingly. On the other hand, reducing the distance between the chip 14 and the chip 16 causes other problems. First, the difficulty of wiring is increased. Second, electromagnetic interference (EMI) between the chips 14 and 16 may occur. In addition, heat dissipation is another issue. Furthermore, when more chips are required to combine a complete electronic system, it becomes more difficult to fabricate the conducting wires 18.

### SUMMARY OF THE INVENTION

It is therefore a primary object of the claimed invention to provide a chip-type micro-connector and method of packaging the same to overcome the aforementioned problems.

According to the claimed invention, a chip-type micro-connector is disclosed. The chip-type micro-connector includes a package substrate, a micro-connector disposed on the package structure, a plurality of chips, and a cap layer disposed on the micro-connector and the chips. The micro-connector includes a connection substrate, a plurality of connecting wires disposed in the connection substrate, and a plurality of contact pads exposed on a surface of the connection substrate and respectively connected to each connecting wire. The chips are coupled to one another via the contact pads and the connecting wires. The cap layer packages the micro-connector and the chips on the package substrate.

According to the claimed invention, a method of packaging a plurality of chips is disclosed. First, a connection substrate is provided. Subsequently, a plurality of connecting wires and a plurality of contact pads electrically connected to the connecting wires are formed in the connection substrate. Thereafter, a plurality of chips electrically connected to the contact pads is provided. Finally, a cap layer is utilized to package the connection substrate and the chips on a package substrate.

The chip-type micro-connector utilizes a micro-connector as a communication medium between chips. The resistance of the connecting wires formed inside the micro-connector can be optimized by adjusting the thickness of the conducting layer and the critical dimension of the connecting wires. Consequently, a better electric connection between the chips is obtained. In comparison with the prior art, the use of the micro-connector reduces the difficulty of wiring, and prevents the heat dissipation and EMI problems.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional package structure.

FIG. 2 and FIG. 3 are schematic diagrams of a chip-type micro-connector according to a preferred embodiment of the present invention.

FIG. 4 is a schematic diagram of a chip-type micro-connector according to another preferred embodiment of the present invention.

FIG. 5 through FIG. 13 are schematic diagrams illustrating a method of packaging a plurality of chips according to the present invention.

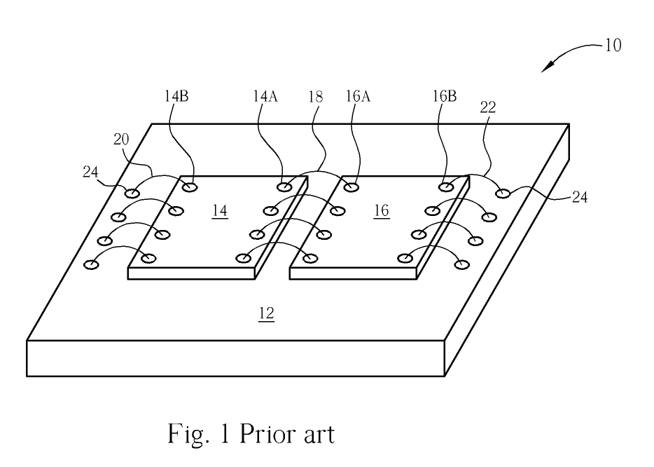

### DETAILED DESCRIPTION

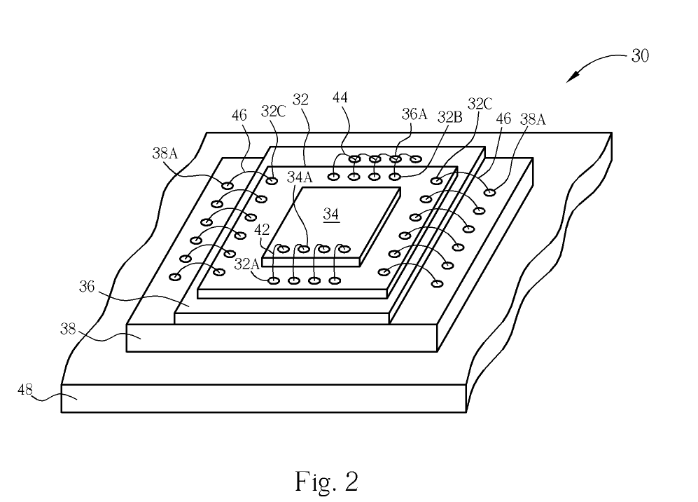

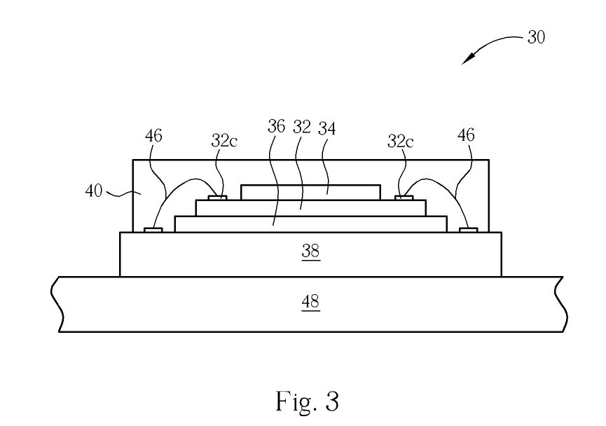

Please refer to FIG. 2 and FIG. 3. FIG. 2 and FIG. 3 are schematic diagrams of a chip-type micro-connector 30 according to a preferred embodiment of the present invention, wherein FIG. 2 is an oblique view, and FIG. 3 is a cross-sectional view. As shown in FIG. 2 and FIG. 3, the chip-type micro-connector 30 of the present invention includes a micro-connector 32, a first chip 34 bonded to the top surface of the micro-connector 32, a second chip 36 bonded to the bottom surface of the micro-connector 32, a package substrate 38 positioned below the second chip 36, and a cap layer 40 disposed above the first chip 34, the micro-connector 32, the second chip 36, and the package substrate 38. The cap layer 40 packages the first chip 34, the micro-connector 32, and the second chip 35 on the package substrate 38.

The micro-connector 32 includes a plurality of connecting wires (not shown). The connecting wires utilize a plurality of contact pads 32A, 32B, and 32C as terminals, where the contact pads 32A are for connecting the first chip 34, the contact pads 32B are for connecting the second chip 36, and the contact chips 32C are for connecting the package substrate 38. In addition, the first chip 34 includes a plurality of contact pads 34A electrically connected to the contact pads 32A of the micro-connector 32 with a plurality of conducting wires 42. The second chip 36 includes a plurality of contact pads 36A electrically connected to the contact pads 32B of the micro-connector 32 with a plurality of conducting wires 44. The connecting wires internally disposed in the micro-connector 32 are designed based on the electrical connection requirement between the first chip 34 and the second chip 36 so that the first chip 34 and the second chip 36 can communicate with each other. The contact pads 32C of the micro-connector 32 are electrically connected to contact pads 38A of the package substrate 38 with a plurality of conducting wires 46, therewith the first chip 34 and the second chip 36 can electrically connect to the package substrate 38. Furthermore, the package substrate 38 is mounted on a PCB 48 by welding or pins (not shown). Accordingly, the first chip 34 and the second chip 36 are coupled to each other via the micro-connector 32, and are further electrically connected to the PCB 48 through the micro-connector 32. In such a manner, the first chip 34 and the second chip 36 form a complete electronic system with other active and passive components disposed on the PCB 48.

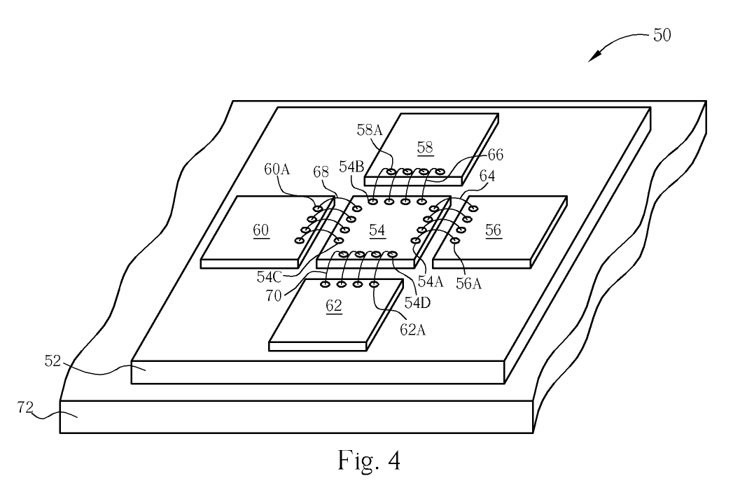

In the above embodiment, the chip-type micro-connector 30 is a vertical type chip-type micro-connector. The configuration of the chip-type micro-connector can also be horizontal type. Please refer to FIG. 4. FIG. 4 is a schematic diagram of a chip-type micro-connector 50 according to another preferred embodiment of the present invention. As shown in FIG. 4, the chip-type micro-connector 50 includes a package substrate 52, a micro-connector 54, a first chip 56, a second chip 58, a third chip 60, and a fourth chip 62. The micro-connector 54, the first chip 56, the second chip 58, the third chip 60, and the fourth chip 62 are all disposed on the surface of the package substrate 52. The micro-connector 54 includes a plurality connecting wires (not shown), and a plurality of contact pads 54A, 54B, 54C, and 54D that serve as terminals. The contact pads 54A are for connecting the first chip 56, the contact pads 54B are for connecting the second chip 58, the contact pads 54C are for connecting the third chip 60, and the contact pads 54D are for connecting the fourth chip 62. In addition, the first chip 56 includes a plurality of contact pads 56A electrically connected to the contact pads 54A of the micro-connector 54 with conducting wires 64. The second chip 58 includes a plurality of contact pads 58A electrically connected to the contact pads 54B of the micro-connector 54 with conducting wires 66. The third chip 60 includes a plurality of contact pads 60A electrically connected to the contact pads 54C of the micro-connector 54 with conducting wires 68. The fourth chip 62 includes a plurality of contact pads 62A electrically connected to the contact pads 54D of the micro-connector 54 with conducting wires 70. The connecting wires internally disposed in the micro-connector 54 are designed based on the electrical connection requirement among the first chip 56, the second chip 58, the third chip 60, and the fourth chip 62. In such a case, the first chip 56, the second chip 58, the third chip 60, and the fourth chip 62 can connect to one another.

In this embodiment, the micro-connector 54 is mounted on the package substrate 52 with solder bumps (not shown) so that the first chip 56, the second chip 58, the third chip 60, and the fourth chip 62 are electrically connected to the package substrate 52. In addition, the package substrate 52 is mounted on a PCB 72 by welding or pins (not shown). By virtue of the above arrangement, the first chip 56, the second chip 58, the third chip 60, and the fourth chip 62 are coupled to one another via the micro-connector 54, and are electrically connected to the PCB 72.

The micro-connector of the present invention works as a communication medium, in which the layout of the connecting wires is designed according to the size of each chip or electrical connection among the chips. For instance, the connecting wires can be a single-layer wiring structure or a multi-layer wiring structure. If a multi-layer wiring structure is adopted, a shielding layer, e.g. a metal layer, can be interposed between each layer for preventing the coupling effect. In addition, the connecting wires layout of the micro-connector can also be more flexible. For example, different sets of connecting wires for different sets of chips can be pre-formed in the micro-connector. When certain sets of chips are adopted, a set of connecting wires for the selected set of chip can be utilized. In such a case, the set of chips can be electrically connected to corresponding contact pads of the set of connecting wires by wiring or other methods. Furthermore, the connection between the each chip and the micro-connector, and the connection between the micro-connector and the package substrate can be implemented by wiring, solder bumps, or other suitable methods where necessary.

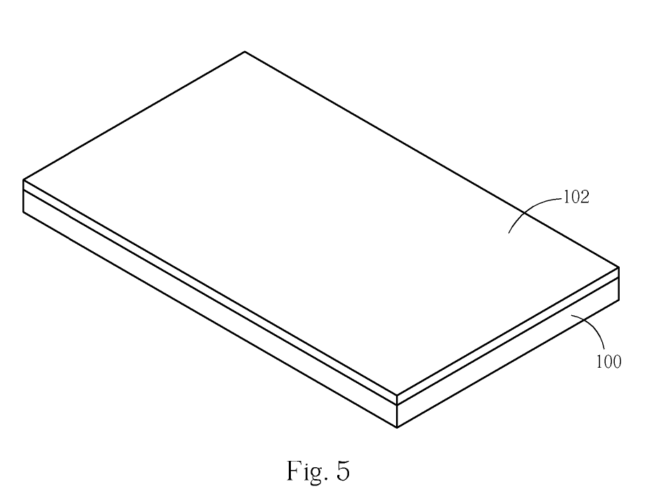

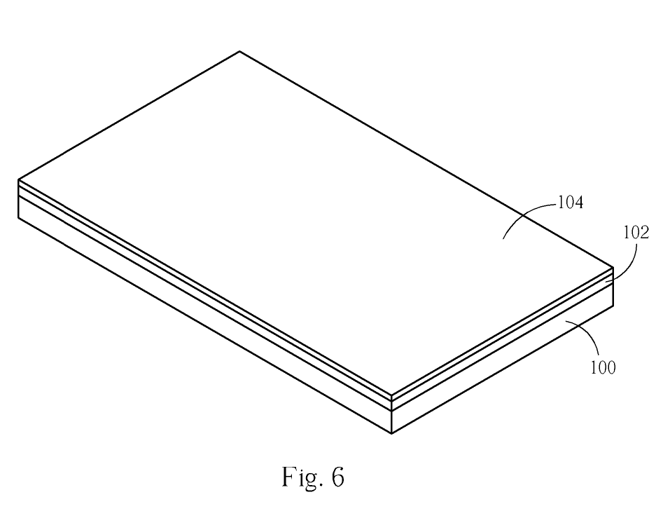

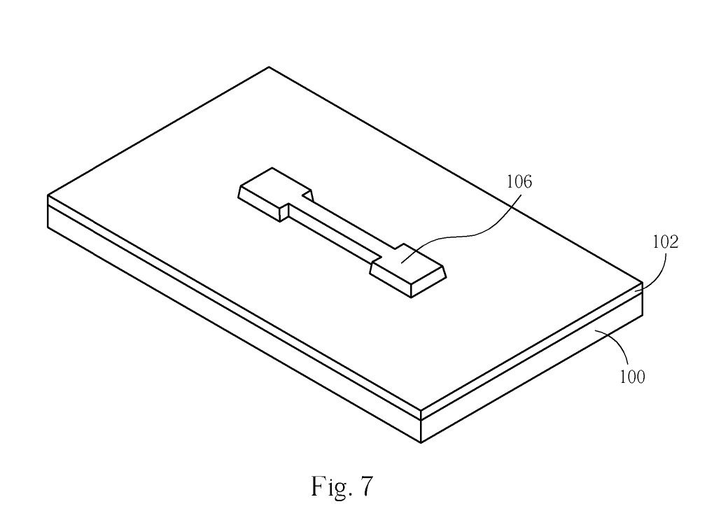

Please refer to FIG. 5 through FIG. 13. FIG. 5 through FIG. 13 are schematic diagrams illustrating a method of packaging a plurality of chips according to the present invention. As shown in FIG. 5, a connection substrate 100, such as a silicon substrate, is provided. Subsequently, a silicon oxide layer 102 serving as a preventable layer and a stress buffer layer is formed on the surface of the connection substrate 100. As shown in FIG. 6 and FIG. 7, a conducting layer 104, e.g. a metal layer, is formed on the silicon oxide layer 102. Subsequently, a photolithographic process and an etching process are performed to partially remove the conducing layer 104 so as to form at least a first connecting wire 106. The thickness of the conducting layer 104 and the critical dimension of the first connecting wire 106 can be adjusted in accordance with the resistance requirement. To obtain a better resistance, the thickness of the conducting layer 104 is preferably larger than 0.5 micrometers, and the critical dimension of the first connecting wire 106 is preferably larger than 10 micrometers.

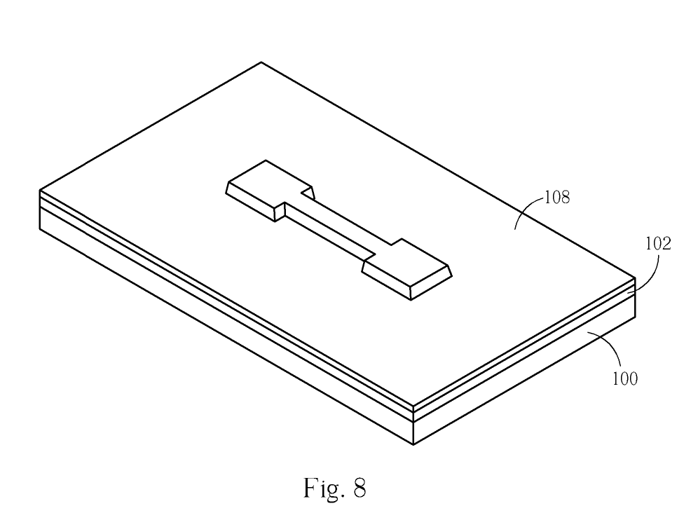

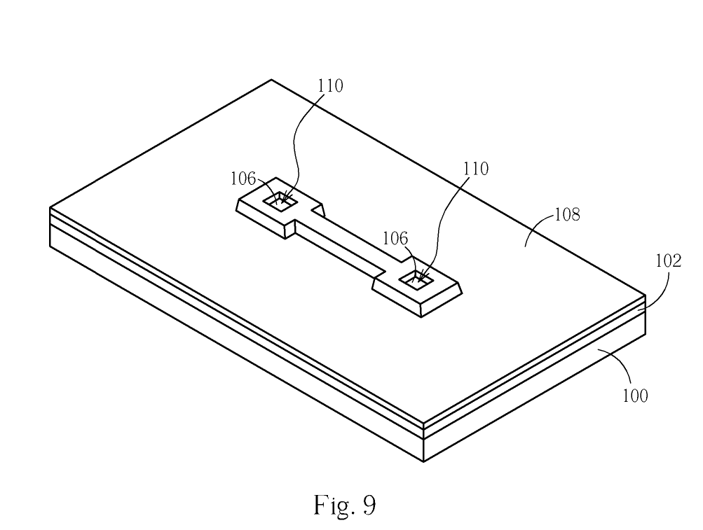

As shown in FIG. 8, a dielectric layer 108, which serves as an insulating layer, is formed on the first connecting wire 106 and the silicon oxide layer 102. As shown in FIG. 9, a photolithographic process and an etching process is carried out to partially remove the dielectric layer 108 so as to form a plurality of contact vias 110. Accordingly, the first connecting wire 106 is partially exposed. Thereafter, a cleaning process is performed to remove oxide and particles adhered to the surface of the first connecting wire 106 in the contact vias 110.

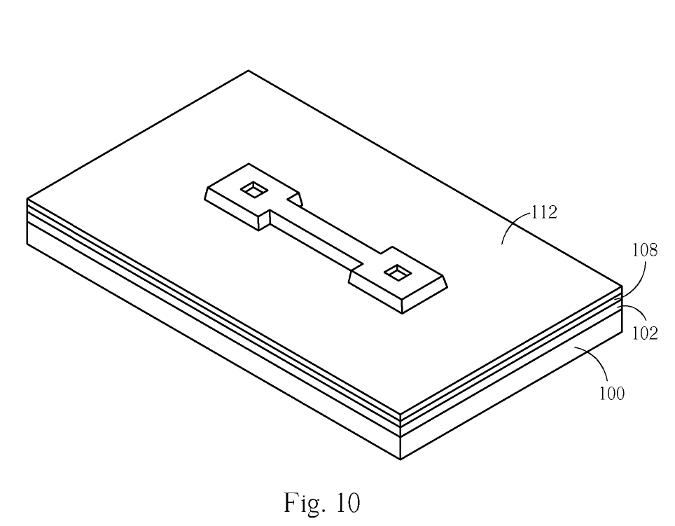

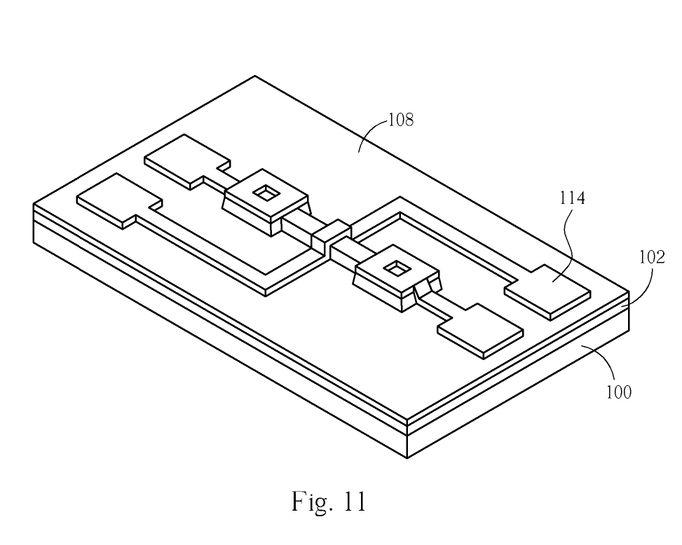

As shown in FIG. 10 and FIG. 11, another conducting layer 112 is formed on the surface of the dielectric layer 108, and a photolithographic process and an etching process are performed to form at least a second connecting wire 114. In this embodiment, the thickness of the conducting layer 112 is preferably larger than 0.5 micrometers, and the critical dimension of the second connecting wire 114 is preferably larger than 10 micrometers.

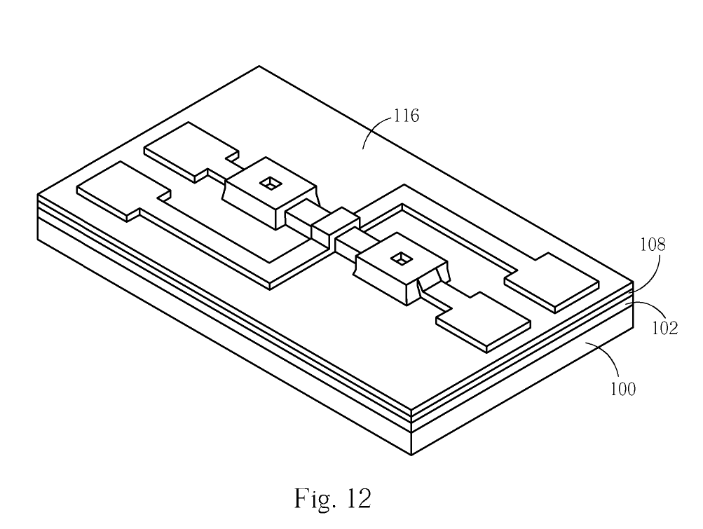

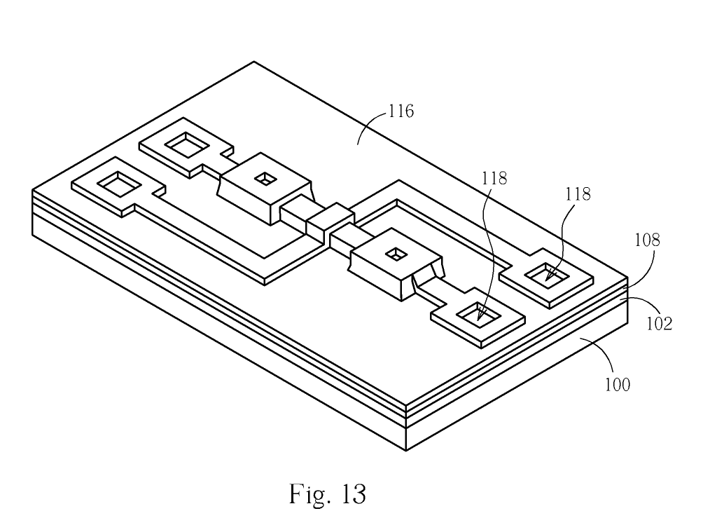

As shown in FIG. 12, a passivation layer 116, e.g. a silicon nitride layer, is formed on the surface of the conducting layer 112. As shown in FIG. 13, a photolithographic process and an etching process is performed to partially remove the passivation layer 116 so as to form a plurality of contact pads 118.

So far, the micro-connector of the present invention is formed. For fabricating a chip-type micro-connector as shown in FIG. 2 or FIG. 4, a plurality of chips are subsequently electrically connected to the contact pads, and a cap layer is utilized to package the chips and the connection substrate on a package substrate. It is noted that FIG. 5 through FIG. 13 illustrate a method of forming a micro-connector with a multi-layer wiring structure. In practice, a micro-connector with a single-layer wiring structure can also be formed in a similar manner.

The chip-type micro-connector utilizes a micro-connector as a communication medium between chips. The resistance of the connecting wires formed inside the micro-connector can be optimized by adjusting the thickness of the conducting layer and the critical dimension of the connecting wires. Consequently, a better electric connection between the chips is obtained. In comparison with the prior art, the use of the micro-connector reduces the difficulty of wiring, and prevents heat dissipation and EMI problems.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of packaging a plurality of chips comprising:
providing a connection substrate;
forming a plurality of connecting wires in the connection substrate, and a plurality of contact pads electrically connected to the connecting wires;
providing a plurality of chips electrically connected to the contact pads; and
utilizing a cap layer to package the connection substrate and the chips on a package substrate.

2. The method of claim 1, wherein steps of forming the connecting wires and the contact pads comprise:
forming at least a dielectric layer on the connection substrate;
forming a conducting layer on the dielectric layer;
partially removing the conducting layer to pattern the plurality of connecting wires;
forming a passivation layer on the dielectric layer and the connecting wires; and
partially removing the passivation layer to form the plurality of contact pads.

3. The method of claim 2, wherein the thickness of the conducting layer is larger than 0.5 micrometers.

4. The method of claim 1, wherein steps of forming the connecting wires and the contact pads comprise:
forming at least a first dielectric layer on the connection substrate;
forming a first conducting layer on the first dielectric layer;
partially removing the first conducting layer to pattern at least a first connecting wire;
forming a second dielectric layer on the first dielectric layer and the first connecting wire;
forming a second conducting layer on the second dielectric layer;
partially removing the second conducting layer to pattern at least a second connecting wire;
forming a passivation layer on the second dielectric layer and the second connecting wire; and
partially removing the passivation layer to form the plurality of contact pads.

5. The method of claim 4, wherein a thickness of the first conducting layer is larger than 0.5 micrometers.

6. The method of claim 4, wherein a thickness of the second conducting layer is larger than 0.5 micrometers.

7. The method of claim 1, wherein a critical dimension of each connecting wire is larger than 0.5 micrometers.
